(19) United States
(12) Patent Application Publication
(10) Pub. No.: US 2026/0223313 A1
(43) Pub. Date: Jul. 30, 2026

(54) Power Distribution System for Server Information Handling System Rack

(71) Applicant: Dell Products L.P., Round Rock, TX (US)

(72) Inventors: Jason Pritchard, Hopkinton, MA (US); Charles Ziegler, East Providence, RI (US); Andrew Barada, Newton, MA (US)

(21) Appl. No.: 19/038,750

(22) Filed: Jan. 28, 2025

(51) Int. Cl. H05K 7/14

(52) U.S. Cl. CPC H05K 7/1492

(57) ABSTRACT

A power distribution system for an information handling system server rack. The power distribution system includes a partial height power distribution unit, the first partial height power distribution unit being configured to be vertically mounted over a first portion of a vertical area of the information handling system server rack, the particle height power distribution unit include a plurality of usable power outlets, each of the plurality of useable power outlets being configured to provide power to a respective information handling system mounted in the information handling system server rack.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system server rack with a power distribution system.

In one embodiment, the invention relates to a power distribution system for an information handling system server rack, comprising: a partial height power distribution unit, the first partial height power distribution unit being configured to be vertically mounted over a first portion of a vertical area of the information handling system server rack, the particle height power distribution unit include a plurality of usable power outlets, each of the plurality of useable power outlets being configured to provide power to a respective information handling system mounted in the information handling system server rack.

In another embodiment, the invention relates to an information handling system server rack comprising: a server rack side panel; and, a power distribution system mounted to the server rack side panel, the power distribution system comprising a partial height power distribution unit, the first partial height power distribution unit being configured to be vertically mounted over a first portion of a vertical area of the information handling system server rack, the particle height power distribution unit include a plurality of usable power outlets, each of the plurality of useable power outlets being configured to provide power to a respective information handling system mounted in the information handling system server rack.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIGS. 3A, 3B and 3C, generally referred to as FIG. 3, show a rack front view, a rack side view, and a rack side view with an information handling system.

FIG. 4 shows a side view of a power distribution system having a pair of power distribution units.

FIGS. 5A and 5B, generally referred to as FIG. 5, show views of a power distribution system with a plurality of power connection configurations.

### DETAILED DESCRIPTION

Various aspects of the present disclosure include an appreciation that it is known to mount a plurality of information handling systems within a server rack. Various aspects of the present disclosure include an appreciation that it is known to provide power to the plurality of information handling systems via a power distribution unit (PDU). Various aspects of the present disclosure include an appreciation that a power distribution unit is often fitted within a plurality of power outlets designed to distribute power to the plurality of information handling systems mounted within the server rack. Various aspects of the present disclosure include an appreciation that a power distribution unit is often configured as a power strip designed to be vertically mounted to the server rack. Various aspects of the present disclosure include an appreciation that a single power distribution unit is often configured as a power strip designed to be vertically mounted over most of the vertical area of the server rack. Various aspects of the present disclosure include an appreciation that the single power distribution unit is often configured to provide up to substantially 34.6 KW of power to the information handling systems mounted in the server rack.

Various aspects of the present disclosure include an appreciation that known power distribution units are often configured with a plurality of outlets. Various aspects of the present disclosure include an appreciation that it is known to known power distribution units are often configured with a plurality of breakers where each breaker supports two or four outlets. Various aspects of the present disclosure include an appreciation that the plurality of breakers are often configured as 16 A breakers. Various aspects of the present disclosure include an appreciation that breakers configured as 16 A breakers are not able to support high-power power supply units such as 3200 W power supply units. Various aspects of the present disclosure include an appreciation that the plurality of outlets of known power distribution units often include different types of outlet connectors. Various aspects of the present disclosure include an appreciation that the plurality of outlets of known power distribution units often include unusable outlets due to incompatible connectors, insufficient breaker current, or a combination thereof.

A system and method are disclosed for providing a power distribution system. In certain embodiments, the power distribution system includes a pair of half height power distribution units. In certain embodiments, the power distribution system is configured to be installed on a server rack.

In certain embodiments, each of the pair of half height power distribution units are configured to provide substantially (i.e., +/−20%) 34.6 KW of electrical power to information handling systems mounted on a respective server rack. In certain embodiments, each of the pair of half height power distribution units includes respective are configured to include a plurality of usable power outlets (i.e., each power outlet of the power distribution unit is usable). In certain embodiments, each power outlet includes a respective outlet breaker. In certain embodiments, each of the pair of half height power distribution units includes a power distribution unit housing which has a form factor which allows multiple power connector locations to be used. In certain embodiments, each power distribution unit can be configured with a top power connection coupled via a top power connector location, a rear power connection coupled via a rear power connector location, or a combination thereof.

Such a power distribution system advantageously provides a double density power distribution system. Such a power distribution system advantageously allows a pair of power distribution units to be mounted on a single server rack. Such a power distribution system advantageously allows use of all the outlets of each of the power distribution units.

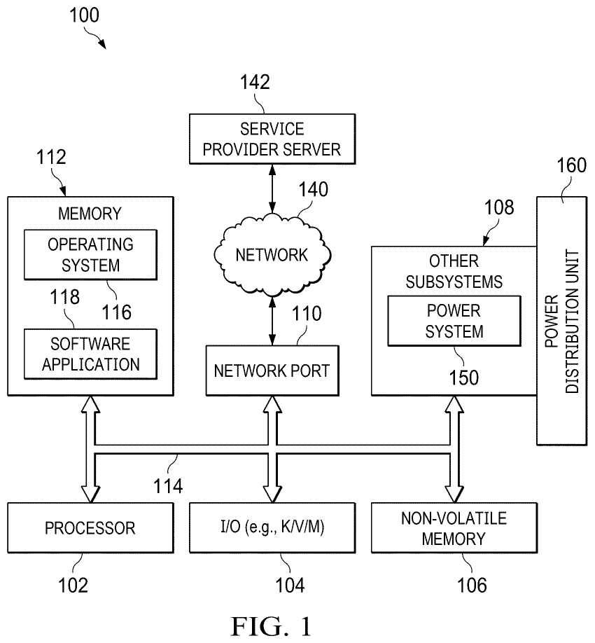

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the information handling system 100 includes a power system 150. In certain embodiments, the power system 150 of the information handling system is coupled to a power distribution system 160. In certain embodiments, the power system 150 includes one or more power supplies. In certain embodiments, the one or more power supplies power various components of the information handling system 100.

In certain embodiments, the power distribution system 160 is configured to be installed to a server rack. In certain embodiments, the power distribution system 160 includes a pair of half height power distribution units. In certain embodiments, the power distribution system 160 is configured to be installed on a server rack.

In certain embodiments, each of the pair of half height power distribution units are configured to provide substantially (i.e., +/−20%) 34.6 KW of electrical power to information handling systems mounted on a respective server rack. In certain embodiments, each of the pair of half height power distribution units includes respective are configured to include a plurality of usable power outlets (i.e., each power outlet of the power distribution unit is usable). In certain embodiments, each power outlet includes a respective outlet breaker. In certain embodiments, each of the pair of half height power distribution units includes a power distribution unit housing which has a form factor which allows multiple power connector locations to be used. In certain embodiments, each power distribution unit can be configured with a top power connection coupled via a top power connector location, a rear power connection coupled via a rear power connector location, or a combination thereof.

Such a power distribution system 160 advantageously provides a double density power distribution system. Such a power distribution system 160 advantageously allows a pair of power distribution units to be mounted on a single server rack. Such a power distribution system advantageously allows use of all the outlets of each of the power distribution units.

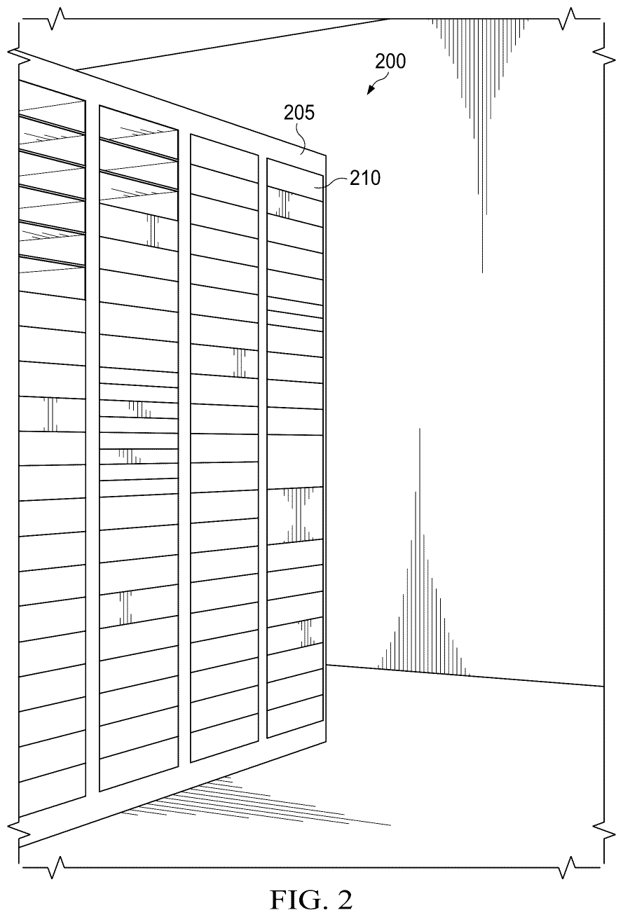

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit and a 4 U rack unit. In general, a 1 U rack unit is substantially (i.e., +/−20%) 1.75″ high, a 2 U rack unit is substantially (i.e., +/−20%) 3.5″ high and a 4 U rack height is substantially (i.e., +/−20%) 7.0″ high. In certain embodiments, the plurality of service sizes includes open rack (OU) server sizes. As used herein, an open rack server size broadly refers to a standardized server system height conforming to an OpenRack standard.

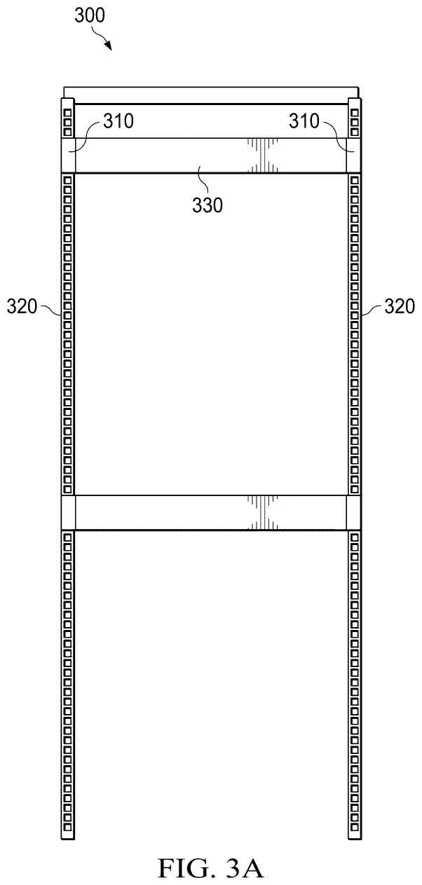

FIGS. 3A, 3B and 3C show a rack front view, a rack side view, and a rack rear view of a rack 300 in which an information handling system is mounted. A first server mounting component 310 is attached to one side of the rack and a second server mounting component 310 is attached to another side of the rack 300. In certain embodiments, the first server mounting component is attached to a first front side panel 320 and a first rear side panel 322 of the rack 300. In certain embodiments, the second server mounting component is attached to a second front side panel 320 and a second rear side panel 322 of the rack 300. In certain embodiments, the first server mounting component 320 is attached via the mounting apertures 330. In certain embodiments, the second server mounting component is attached via the mounting apertures 330.

In certain embodiments, the rack has a plurality of dimensions. In certain embodiments, the plurality of dimensions includes a width dimension, a depth dimension, a height dimension, or a combination thereof. In certain embodiments, the width dimension is defined by a distance from the first front side panel 320 and the second front side panel 320. In certain embodiments, the depth dimension of the rack is defined by a distance from a front side panel 320 and a rear side panel 322. In certain embodiments, the height dimension is defined by a distance from a bottom of a side panel 320 to a top of the side panel 320.

In certain embodiments, a rack includes a plurality of vertically arranged mounting components. In certain embodiments, some or all of the vertically arranged mounting components are adapted to mount respective rack server type information handling systems to the rack. In certain embodiments, the server mounting components are configured to correspond to particular heights including rack unit heights and open unit heights.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the rack system 300 includes a power distribution system 350. In certain embodiments, the power distribution system 350 corresponds to power distribution system 160. In certain embodiments, the power distribution system 350 is configured to be installed to the server rack 300. In certain embodiments, the power distribution system 350 is configured to be installed on a rear side panel 322. In certain embodiments, the power distribution system 350 includes a pair of half height power distribution units. In certain embodiments, the power distribution units are configured to be installed on the server rack 300.

In certain embodiments, each of the pair of half height power distribution units are configured to provide substantially (i.e., +/−20%) 34.6 KW of electrical power to information handling systems mounted on a respective server rack. In certain embodiments, each of the pair of half height power distribution units includes respective are configured to include a plurality of usable power outlets (i.e., each power outlet of the power distribution unit is usable). In certain embodiments, each power outlet includes a respective outlet breaker. In certain embodiments, each of the pair of half height power distribution units includes a power distribution unit housing which has a form factor which allows multiple power connector locations to be used. In certain embodiments, each power distribution unit can be configured with a top power connection coupled via a top power connector location, a rear power connection coupled via a rear power connector location, or a combination thereof.

Such a power distribution system 160 advantageously provides a double density power distribution system. Such a power distribution system 160 advantageously allows a pair of power distribution units to be mounted on a single server rack. Such a power distribution system advantageously allows use of all the outlets of each of the power distribution units.

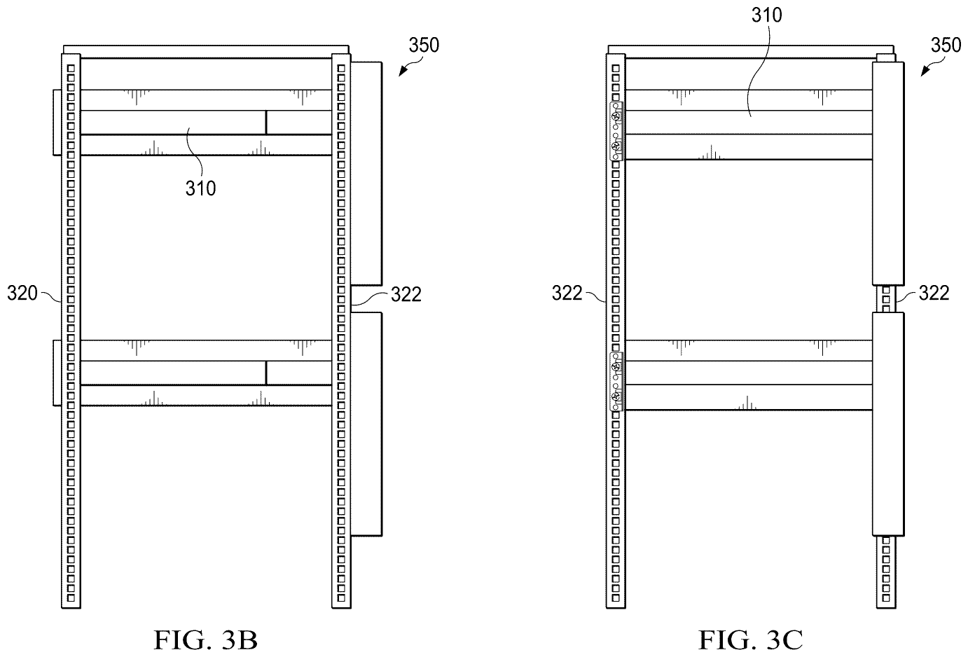

FIG. 4 shows a side view of a power distribution system 400 having a pair of power distribution units. In certain embodiments, the power distribution system 400 corresponds to power distribution system 160.

In certain embodiments, the power distribution system 400 includes a first partial height power distribution unit (PDU1), a second partial half height power distribution unit (PDU2), or a combination thereof. In certain embodiments, the first partial height power distribution unit is configured to be vertically mounted over a first portion of a vertical area of the server rack. In certain embodiments, the second partial height power distribution unit is configured to be vertically mounted over a second portion of a vertical area of the server rack. In certain embodiments, the first partial height power distribution unit and the second partial height power distribution unit are designed to be vertically mounted one on top of the other on a server rack. In certain embodiments, the first partial height power distribution unit and the second partial height power distribution unit are configured to be vertically mounted over most (i.e., more than 75%) of the vertical area of a server rack.

In certain embodiments, the first partial height power distribution unit includes a first half height power distribution unit 410. In certain embodiments, the second partial half height power distribution unit includes a second half height power distribution unit 412. In certain embodiments, the first half height power distribution unit 410 is configured as a power strip designed to be vertically mounted over a first half of the vertical area of the server rack. In certain embodiments, the second half height power distribution unit 412 is configured as a power strip designed to be vertically mounted over a second half of the vertical area of the server rack. In certain embodiments, the first half height power distribution unit 410 and second half height power distribution unit 412 are designed to be vertically mounted one on top of the other on a server rack. In certain embodiments, the first half height power distribution unit 410 and second half height power distribution unit 412 are configured to be vertically mounted over most (i.e., more than 75%) of the vertical area of a server rack.

In certain embodiments, the first half height power distribution unit 410, the second half height power distribution unit 412, or a combination thereof, are each configured to provide substantially (i.e., +/−20%) 34.6 KW of electrical power to information handling systems mounted on a respective server rack. In certain embodiments, the first half height power distribution unit 410 and the second half height power distribution unit 412 are each configured to provide substantially (i.e., +/−20%) 69.2 KW of electrical power to information handling systems mounted on a respective server rack. In certain embodiments, the first half height power distribution unit 410 is configured to provide substantially (i.e., +/−20%) 34.6 KW of electrical power to information handling systems mounted on a top half of a respective server rack. In certain embodiments, the second half height power distribution unit 412 is configured to provide substantially (i.e., +/−20%) 34.6 KW of electrical power to information handling systems mounted on a bottom half of a respective server rack.

In certain embodiments, the first half height power distribution unit 410, the second half height power distribution unit 412, or a combination thereof, includes a plurality of usable power outlets 420. As used herein, a plurality of usable power outlets broadly refers to a configuration of power outlets where each power outlet of the power distribution unit is usable at the same time, i.e., each power outlet may be coupled to a respective information handling system mounted in the server rack and function properly to provide power to the respective information handling system. In certain embodiments, the first half height power distribution unit 410, the second half height power distribution unit 412, or a combination thereof, include twelve useable power outlets (B1, B2, B3, B4, B5, B6, B7, B8, B9, B10, B11, B12). In certain embodiments, the usable power outlets 420 are arranged in sets of three usable power outlets. In certain embodiments, the usable power outlets 420 are arranged in as four sets of usable power outlets. In certain embodiments, a first set of usable power outlets includes power outlets B1, B2 and B3. In certain embodiments, a second set of usable power outlets includes power outlets B4, B5 and B6. In certain embodiments, a third set of usable power outlets includes power outlets B7, B8 and B9. In certain embodiments, a fourth set of usable power outlets includes power outlets B10, B11 and B12.

In certain embodiments, the usable power outlets are configured to operate in a three-phase power configuration. In certain embodiments, certain usable power outlets are configured to operate in a first phase power configuration, certain usable power outlets are configured to operate in a second phase power configuration and certain usable power outlets are configured to operate in a third phase power configuration. In certain embodiments, power outlets B2, B3, B7 and B10 are configured to operate in a first phase power configuration, power outlets B1, B6, B8 and B11 are configured to operate in a second phase power configuration and power outlets B4, B5, B9 and B12 are configured to operate in a third phase power configuration.

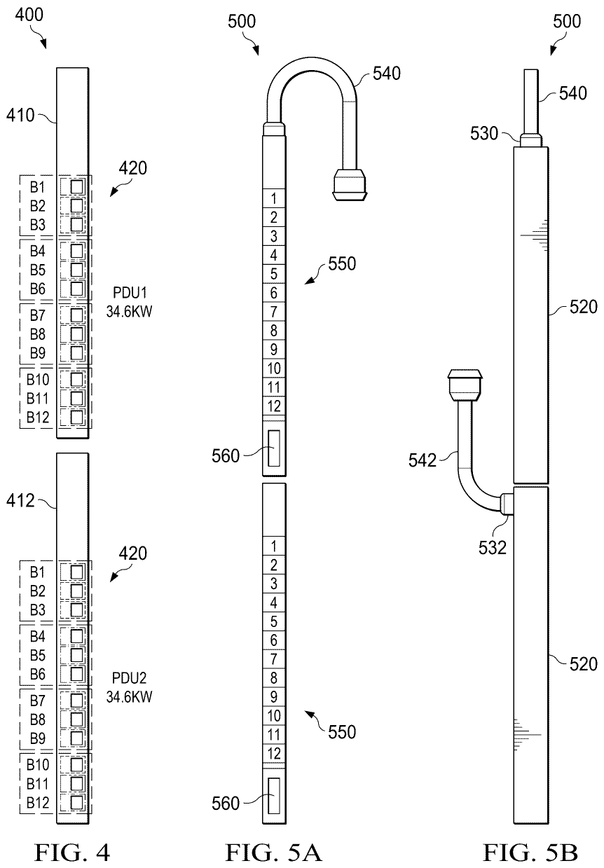

FIGS. 5A and 5B, generally referred to as FIG. 5, show a plurality of views of power distribution system 500 with a plurality of power connection configurations. In certain embodiments, FIG. 5A shows a front view of power distribution system 500 with a plurality of power connection configurations. FIG. 5B shows a side view of power distribution system 500 with a plurality of power connection configurations. In certain embodiments, the power distribution system 500 corresponds to power distribution system 160.

In certain embodiments, each power distribution unit includes a respective power distribution unit housing 520. In certain embodiments, each power distribution unit housing 520 has a form factor which allows multiple power connector locations to be used. In certain embodiments, each power distribution unit can be configured with a top power connection 530 coupled via a top power connector location, a rear power connection 532 coupled via a rear power connector location, or a combination thereof. In certain embodiments, each power connection includes an alternating current (AC) power connection. In certain embodiments, each power connection includes a respective AC cable whip. In certain embodiments, the top power connection includes a respective top AC cable whip 540. In certain embodiments, the rear power connection includes a respective rear AC cable whip 542. In certain embodiments, the top power connection is positioned along a top edge of the respective half height power distribution unit. In certain embodiments, the rear power connection is positioned close to a top edge of the respective half height power distribution unit.

In certain embodiments, the first half height power distribution unit 410, the second half height power distribution unit 412, or a combination thereof, includes a plurality of outlet breakers 550. In certain embodiments, each outlet of the first half height power distribution unit 410, the second half height power distribution unit 412, or a combination thereof, includes a respective outlet breaker. In certain embodiments, each power outlet (B1, B2, B3, B4, B5, B6, B7, B8, B9, B10, B11, B12) includes a respective outlet breaker (1, 2, 3, 4, 5, 6, 7, 8, 9, 10, 11, 12). In certain embodiments, each outlet breaker is positioned in the power distribution unit behind its respective power outlet. In certain embodiments, each outlet breaker is positioned in the power distribution unit to be accessible when the power distribution unit is mounted to a server rack.

In certain embodiments, the first half height power distribution unit 410, the second half height power distribution unit 412, or a combination thereof, includes a respective network management device 560. In certain embodiments, each network management device is positioned within the respective half height power distribution unit along a portion of the respective half height power distribution unit opposite to the location of the power connection of the power distribution unit. In certain embodiments, each network management device is positioned within the respective half height power distribution unit close to a bottom edge of the respective half height power distribution unit

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A power distribution system for an information handling system server rack, comprising:
a partial height power distribution unit, the first partial height power distribution unit being configured to be vertically mounted over a first portion of a vertical area of the information handling system server rack, the particle height power distribution unit include a plurality of usable power outlets, each of the plurality of useable power outlets being configured to provide power to a respective information handling system mounted in the information handling system server rack.

2. The power distribution system of claim 1, further comprising:
a second partial height power distribution unit, the second partial height power distribution unit being configured to be vertically mounted over a second portion of a vertical area of the information handling system server rack, the second particle height power distribution unit including a second plurality of usable power outlets, each of the second plurality of useable power outlets being configured to provide power to other respective information handling systems mounted in the information handling system server rack.

3. The power distribution system of claim 2, wherein:
the partial height power distribution unit and the second partial half height power distribution unit are vertically mounted one on top of the other on the information handling system server rack.

4. The power distribution system of claim 1, wherein:
the partial height power distribution unit includes a plurality of outlet breakers; and, each of the plurality of usable outlets has an associated outlet breaker from the plurality of outlet breakers.

5. The power distribution system of claim 1, wherein:
the partial height power distribution unit includes a power distribution unit housing, the power distribution unit housing being configured to allow a plurality of power connector locations to be used with the power distribution unit housing.

6. The power distribution system of claim 5, wherein:
the plurality of power connector locations includes a top power connector location and a rear power connector location.

7. An information handling system server rack comprising:
a server rack side panel; and,
a power distribution system mounted to the server rack side panel, the power distribution system comprising
a partial height power distribution unit, the first partial height power distribution unit being configured to be vertically mounted over a first portion of a vertical area of the information handling system server rack, the particle height power distribution unit include a plurality of usable power outlets, each of the plurality of useable power outlets being configured to provide power to a respective information handling system mounted in the information handling system server rack.

8. The information handling system server rack of claim 7, wherein the power distribution system further comprises:
a second partial height power distribution unit, the second partial height power distribution unit being configured to be vertically mounted over a second portion of a vertical area of the information handling system server rack, the second particle height power distribution unit including a second plurality of usable power outlets, each of the second plurality of useable power outlets being configured to provide power to other respective information handling systems mounted in the information handling system server rack.

9. The information handling system server rack of claim 8, wherein:
the partial height power distribution unit and the second partial half height power distribution unit are vertically mounted one on top of the other on the information handling system server rack.

10. The information handling system server rack of claim 7, wherein:
the partial height power distribution unit includes a plurality of outlet breakers; and,
each of the plurality of usable outlets has an associated outlet breaker from the plurality of outlet breakers.

11. The information handling system server rack of claim 7, wherein:
the partial height power distribution unit includes a power distribution unit housing, the power distribution unit housing being configured to allow a plurality of power connector locations to be used with the power distribution unit housing.

12. The information handling system server rack of claim 11, wherein:
the plurality of power connector locations includes a top power connector location and a rear power connector location.
